(19) United States
(12) Patent Application Publication
(10) Pub. No.: US 2018/0301488 A1
(43) Pub. Date: Oct. 18, 2018

(54) IMAGE SENSING CHIP PACKAGING STRUCTURE AND PACKAGING METHOD

(71) Applicant: China Wafer Level CSP Co., Ltd., Suzhou, Jiangsu (CN)

(72) Inventors: Zhiqi Wang, Suzhou, Jiangsu Province (CN); Guoliang Xie, Suzhou, Jiangsu (CN); Zhixiong Jin, Suzhou, Jiangsu (CN); Junjie Li, Suzhou (CN)

(73) Assignee: China Wafer Level CSP Co., Ltd., Suzhou, Jiangsu (CN)

(21) Appl. No.: 15/767,096

(22) PCT Filed: Oct. 28, 2015
(86) PCT No.: PCT/CN2016/099325

§ 371 Date: Apr. 9, 2018

(30) Foreign Application Priority Data
Oct. 28, 2015 (CN) 201510716297.6
Oct. 28, 2015 (CN) 201520848187.0

(51) Int. Cl. H01L 27/146

(52) U.S. Cl. CPC H01L 27/14618; H01L 27/14632; H01L 27/14687; H01L 2224/13022; H01L 27/14636; H01L 2224/0401; H01L 27/1469

(57) ABSTRACT

A package and a packaging method for an image sensing chip are provided. The package includes: an image sensing chip having a first surface and a second surface opposite to each other, where the first surface is provided with an image sensing region and a contact pad around the image sensing region; a through hole extending from the second surface to the contact pad; a passivation layer provided on a side wall of the through hole and on the second surface; an electrical connection layer provided on a bottom of the through hole and on the passivation layer, where the electrical connection layer is electrically connected with the contact pad; and a solder bump electrically connected with the electrical connection layer.

This application claims the priority to the Chinese Patent Application No. 201510716297.6, titled “IMAGE SENSING CHIP PACKAGING STRUCTURE AND PACKAGING METHOD” and filed with the Chinese State Intellectual Property Office on Oct. 28, 2015, and the priority to the Chinese Patent Application No. 201520848187.0, titled “IMAGE SENSING CHIP PACKAGING STRUCTURE” and filed with the Chinese State Intellectual Property Office on Oct. 28, 2015, which are incorporated herein by reference in their entireties.

### FIELD

The present disclosure relates to the technical field of semiconductors, and in particular to a package and a packaging method for an image sensing chip.

### BACKGROUND

According to the current wafer level packaging technology, a whole wafer is tested and packaged, and is cut to obtain individual finished chips. The wafer level packaging technology gradually replaces the wire bonding packaging technology, and becomes the mainstream packaging technology.

Image sensors are generally packaged using the wafer level packaging technology. FIG. 1 shows a conventional package for an image sensing chip, which includes an image sensing chip 10 and a cover plate 20. An image sensing region 12 and a contact pad 14 are arranged on a first surface of the image sensing chip, the cover plate 20 is arranged above the image sensing region 12 for protecting the image sensing region. The cover plate 20 generally includes a glass substrate 22 and a support structure 24 on the glass substrate 22, where a cavity is formed by the support structure 24. After the support structure 24 is bonded to the first surface where the image sensing region is located, the image sensing region 12 is located in the cavity and is protected. A guide hole extending to the contact pad 14 and a solder bump 22 electrically connected with the guide hole are arranged on a second surface of the image sensing chip for external electrical connection. The guide hole includes an insulation layer 16, an electrical connection layer 18 and a solder mask 20 which are arranged in a through hole and on the second surface on two sides of the through hole. The solder bump 22 is formed on the electrical connection layer 18 on a side of the through hole, for enabling external electrical connection of the contact pad.

However, in this structure, the insulation layer 16 is generally made of an organic material. The insulation layer made of the organic material is weak at corners of the through hole, especially a step-shaped through hole (not shown in FIG. 1), resulting in the through hole being susceptible to defects at corners. In addition, when the electrical connection layer is subsequently formed, an opening is formed in the insulation layer using a laser, and the insulation layer and the contact pad are punctured after the opening is formed. In this way, as shown in FIG. 1, an electrical connection is formed between the formed electrical connection layer 18 and a side wall of the contact pad 14, where the connection has a small contact area, and is susceptible to fracture or even failure when the wafer is under stress.

### SUMMARY

In view of this, a package for an image sensing chip is provided according to a first aspect of the present disclosure to reduce defects of the package for the image sensing chip.

To address the above issue, a package for an image sensing chip is provided according to an embodiment of the present disclosure. The package includes: an image sensing chip having a first surface and a second surface opposite to each other, where the first surface is provided with an image sensing region and a contact pad around the image sensing region; a through hole extending from the second surface to the contact pad; a passivation layer provided on a side wall of the through hole and on the second surface; an electrical connection layer provided on a bottom of the through hole and on the passivation layer, where the electrical connection layer is electrically connected with the contact pad; and a solder bump electrically connected with the electrical connection layer.

Preferably, the package may further include a light shielding layer located on the second surface and covering the image sensing region.

Preferably, the light shielding layer may be made of metal.

Preferably, the metal may be Al, of which a surface is blackened.

Preferably, the package may further include a buffer layer located between the electrical connection layer and the passivation layer.

Preferably, the buffer layer may be made of an organic macromolecule photoresist or a photosensitive resist.

Preferably, a thickness of the buffer layer may range from 5 μm to 25 μm.

Preferably, the package may further include a solder mask covering the electrical connection layer and filling the through hole.

Preferably, the package may further include a protective cover plate attached and aligned with the image sensing chip.

Preferably, the protective cover plate may be made of optical glass, and an anti-reflection layer is arranged on at least one surface of the optical glass.

Preferably, the passivation layer may be made of silicon oxide, silicon nitride or silicon oxynitride.

According to another embodiment of the present disclosure, a method for packaging an image sensing chip is provided. The method includes: providing a wafer including multiple image sensing chips arranged in an array, where each of the multiple image sensing chips has a first surface and a second surface opposite to each other, and includes an image sensing region and a contact pad around the image sensing region, with the image sensing region and the contact pad being located on the first surface; forming a through hole on the second surface, where the through hole extends to the contact pad; forming a passivation layer on a side wall of the through hole and on the second surface on two sides of the through hole; forming an electrical connection layer covering an inner wall of the through hole and a buffer layer, where the electrical connection layer is electrically connected with the contact pad; and forming a solder bump on the electrical connection layer, where the solder bump is electrically connected with the electrical connection layer.

Preferably, before the forming the through hole, the method may further include forming a light shielding layer at a position on the second surface corresponding to the image sensing region.

Preferably, the forming the light shielding layer may include forming a metal layer on the second surface by sputtering, and etching the metal layer, to form the light shielding layer at the position corresponding to the image sensing region.

Preferably, the metal layer may be made of Al, and after forming the metal layer made of Al by sputtering, the method may further include: blackening a surface of the metal layer, and then etching the metal layer.

Preferably, after the forming the electrical connection layer and before the forming the solder bump, the method may further include: forming a solder mask, and forming an opening in the solder mask on the second surface, where the solder bump is formed in the opening.

Preferably, the method may further include: providing a protective cover plate, and attaching and aligning the protective cover plate with the image sensing chip.

Preferably, the protective cover plate may be made of optical glass, and an anti-reflection layer may be arranged on at least one surface of the optical glass.

Preferably, the forming the passivation layer on the side wall of the through hole and on the second surface on two sides of the through hole may include: depositing a passivation layer; and removing the passivation layer at a bottom of the through hole by etching.

Preferably, the passivation layer may be made of silicon oxide, silicon nitride or silicon oxynitride.

Preferably, after the forming the passivation layer, the method may further include: forming the buffer layer on the passivation layer on the second surface.

Preferably, the buffer layer may be made of a photosensitive resist, and the forming the buffer layer on the passivation layer on the second surface may include: spin-coating the photosensitive resist on the second surface; and forming the buffer layer with an exposure and development process.

In the package and the packaging method for the image sensing chip according to the embodiments of the present disclosure, a passivation layer is arranged between the electrical connection layer and the chip and functions as an insulation layer. The passivation layer has good step coverage, even at the corners of the through hole. In addition, a buffer layer is arranged between the electrical connection layer and the passivation layer under the solder bump, for absorbing an impact force to the passivation layer caused by reflow soldering when the solder bump is formed. Further, the passivation layer at the bottom of the through hole may be removed by etching, to expose the contact pad. In this way, a surface to surface contact with a great area is formed between the electrical connection layer formed subsequently and the contact pad, thereby increasing a bonding force between the electrical connection layer and the contact pad, and further reducing potential defects in the package for the image sensing chip.

### BRIEF DESCRIPTION OF THE DRAWINGS

FIG. 1 shows a sectional view illustrating a structure of a package for an image sensing chip according to the conventional technology;

FIG. 2 shows a sectional view illustrating a structure of a package for an image sensing chip according to an embodiment of the present disclosure;

FIG. 3 shows a sectional view illustrating a structure of a package for an image sensing chip according to another embodiment of the present disclosure; and

FIGS. 4A to 13 show schematic structural diagrams of intermediate structures formed during implementation of a packaging method for an image sensing chip according to an embodiment of the present disclosure.

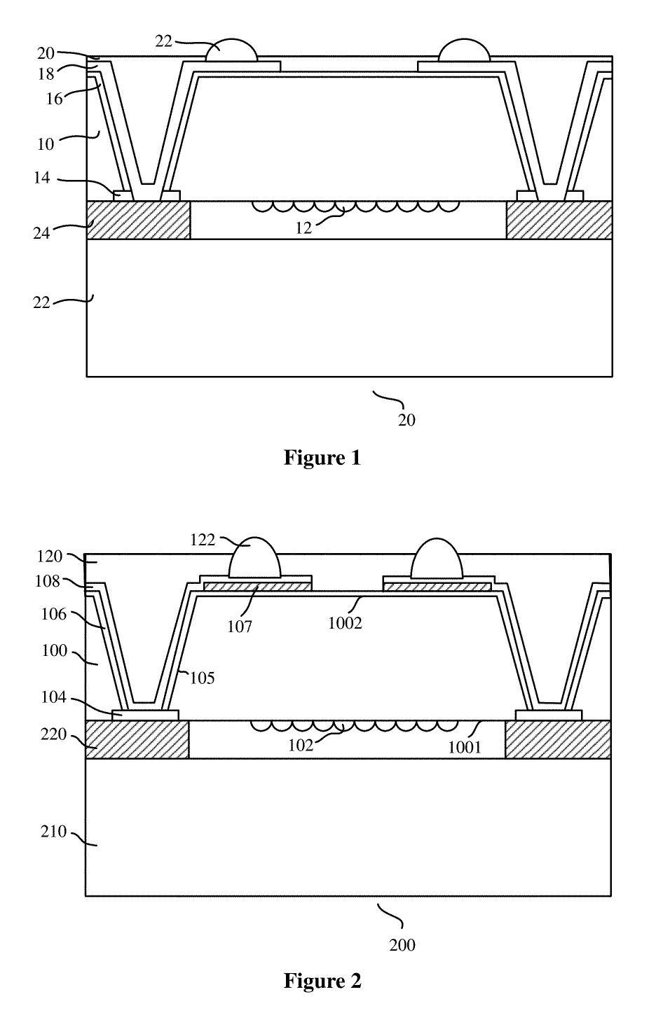

### DETAILED DESCRIPTION OF THE EMBODIMENTS

In order that the objectives, features and advantages of the present disclosure can be clearer, the embodiments of the present disclosure are described in detail as follows in conjunction with the drawings.

Specific details are described in the following description so that the present disclosure can be understood completely. However, the present disclosure may also be embodied in other ways different from the way described herein, a similar extension can be made by those skilled in the art without departing from intension of the present disclosure. Therefore, the present disclosure is not limited to the specific embodiments described below.

In addition, the present disclosure is described in detail in conjunction with the schematic diagrams. When describing the embodiments of the present disclosure in detail, sectional views showing the structure of the device are not partially enlarged to a certain scale for ease of illustration. Moreover, the schematic diagrams are only examples, which should not be understood as limiting the scope of the disclosure. Furthermore, in an actual manufacture process, three-dimensioned measurements, i.e. the length, the width and the depth should be considered. Additionally, a structure in which the first feature is “on” the second feature described below may include embodiments in which the first and second features are formed in direct contact, and may also include an embodiment in which additional features are formed between the first and second features, in this case, the first and second features may not be in direct contact.

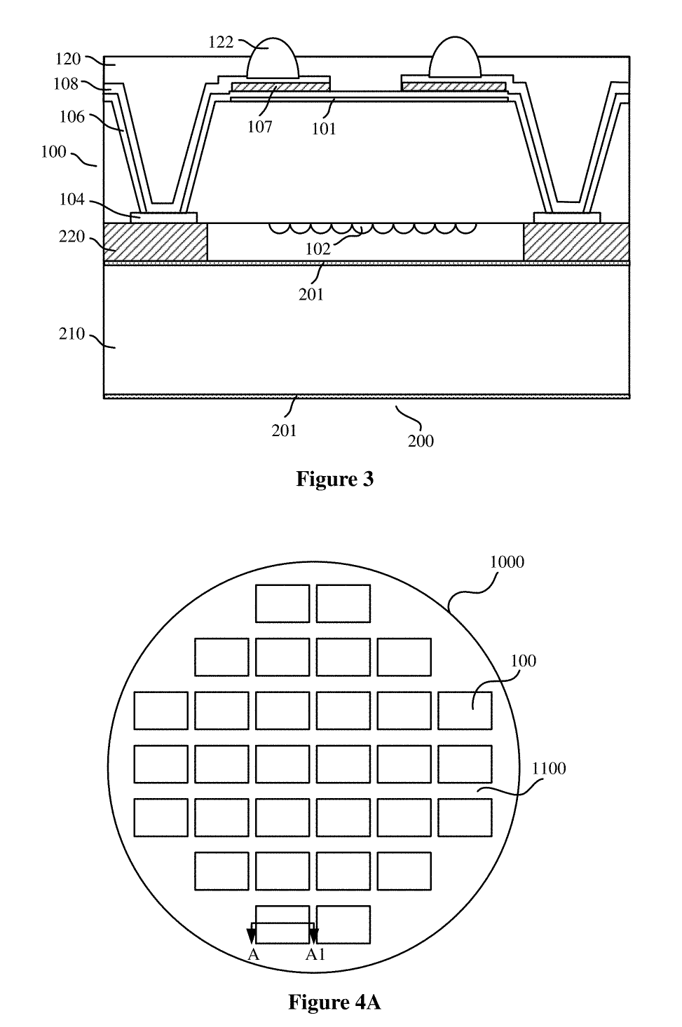

In order to reduce defects in a package for an image sensing chip, especially defects of weakness at corners of the through hole, a package for an image sensing chip is provided in the present disclosure. As shown in FIG. 2 and FIG. 3, the package for an image sensing chip includes:

an image sensing chip 100, including a first surface 1001 and a second surface 1002 opposite to each other, where the first surface 1001 is provided with an image sensing region 102 and a contact pad 104 around the image sensing region 102;

a through hole 105 extending from the second surface 1002 to the contact pad 104;

a passivation layer 106 arranged on a side wall of the through hole 105 and on the second surface 1002;

an electrical connection layer 108 arranged on a bottom of the through hole 105 and on the passivation layer 106, where the electrical connection layer 108 is electrically connected with the contact pad 104; and

a solder bump 122 electrically connected with the electrical connection layer 108.

In the present disclosure, a passivation layer is arranged between the electrical connection layer and the chip and functions as an insulation layer. The passivation layer has good step coverage, even at the corners of the through hole. Further, the passivation layer at the bottom of the through hole may be removed by etching, to expose the contact pad. In this way, a surface to surface contact with a great area is formed between the electrical connection layer formed subsequently and the contact pad, thereby increasing a bonding force between the electrical connection layer and the contact pad, and further reducing potential defects in the package for the image sensing chip.

In another example of the present disclosure, the package further includes a buffer layer 107 located between the electrical connection layer 108 and the passivation layer 106. By arranging the buffer layer between the electrical connection layer and the passivation layer under the solder bump, an impact force to the passivation layer caused by reflow soldering when the solder bump is formed can be absorbed.

In the embodiment of the present disclosure, the package for an image sensing chip may be a structure in which the guiding hole and the solder bump are formed, and which is not cut, or may be an individual finished chip structure obtained after cutting.

The image sensing chip includes at least the image sensing region and the contact pad. In the embodiments of the present disclosure, the image sensing region 102 and the contact pad 104 around the image sensing region 102 are arranged on the first surface of the image sensing chip. The image sensing region 102 is used for receiving external light and converting the external light into an electrical signal. At least an image sensor unit is formed in the image sensing region 102. An association circuit connected with the image sensor unit may be further formed in the image sensing region 102. The association circuit may be a driving unit (not shown in the drawings) for driving the chip, a reading unit (not shown in the drawings) for acquiring a photosensitive region current, a processing unit (not shown in the drawings) for processing the photosensitive region current, and the like.

Apparently, other components may also be provided on the image sensing chip according to specific design requirements. However, the components which are not closely related to the inventive aspects of the present disclosure are not described in detail herein.

Generally, in order to facilitate wiring, the image sensing region 102 is located at the center of a single chip unit, contact pads 104 are arranged in a rectangular configuration around the image sensing region 102 and at the periphery of the single chip unit, where several contact pads 104 may be formed on each side of the single chip unit. The contact pad 104 is an input/output terminal between a component in the image sensing region and an external circuit, through which the electrical signal from the image sensing region 102 is transmitted to the external circuit. The contact pad is made of a conductive material, which may be a metal material such as Al, Au, or Cu.

It should be understood that the positions of the image sensing region and the contact pads, as well as the number of the contact pads may be adjusted according to different designs and requirements. For example, the contact pads may be provided on only one side or two sides of the image sensing region.

Preferably, but not necessarily, the package for an image sensing chip may further include a protective cover plate 200 attached and aligned with the image sensing region 102. The protective cover plate 200, which functions to protect the components in the image sensing region 102, includes a space for containing the image sensing region, so that a protective cover is formed on the image sensing region, thereby protecting the image sensing region from damage without affecting the light entering the image sensing region. In an embodiment of the present disclosure, the protective cover plate 200 is made of optical glass, on which a support structure 220 is provided. The protective cover plate 200 is attached and aligned with the image sensing region 102 via the support structure 220, so that the image sensing region 102 is contained in a cavity formed by the support structure 220, thereby forming a glass cover for protecting the image sensing region 102. It should be understood that the protective cover plate 200 may have other structures. For example, the protective cover plate 200 may be formed by an opaque substrate, and an opening or a light-transmitting opening with a shield is provided at a region of the substrate corresponding to the image sensing region.

However, the protective cover plate made of the optical glass may have a defect of specular reflection, which causes reduction of the light entering the image sensing region and affects the imaging quality. Therefore, referring to FIG. 3, in an embodiment of the present disclosure, an anti-reflection layer 201 is provided on a surface of the protective cover plate 200 made of optical glass. The anti-reflection layer 201 may be arranged on a surface of the optical glass facing the image sensing region 102 or a surface opposite to the surface facing the image sensing region 102. Alternatively, the anti-reflection layer 201 may be provided on both surfaces of the optical glass. The anti-reflection layer covers at least a region corresponding to the image sensing region 102. A suitable material of the anti-reflection coating may be selected according to the selected optical glass. The reflected light can be reduced, the light entering the image sensing region can be increased, and the imaging quality can be improved by providing the anti-reflection layer on the surface of the optical glass.

In the present disclosure, the contact pad 104 is electrically connected with an external circuit via the through hole 105, to transmit the electrical signal from the image sensing region 102 to the external circuit.

In the embodiment of the present disclosure, as shown in FIG. 2 and FIG. 3, the contact pad 104 is electrically connected with the external circuit through the following components: the through hole 105 extending from the second surface 1002 to the contact pad 104, the passivation layer 106 arranged on the side wall of the through hole 105 and on the second surface 1002, the electrical connection layer 108 arranged on the bottom of the through hole 105 and on the passivation layer 106, and the solder bump 122 electrically connected with the electrical connection layer 108. In addition, a buffer layer 107 may be arranged between the electrical connection layer 108 and the passivation layer 106, to absorb an impact force to the passivation layer in the process of soldering the bump.

The through hole 105 extends through the image sensing chip 100 to the contact pad 104, so that the contact pad 104 is exposed through the through hole 105. The through hole 105 may extend to the surface of the contact pad 104, or may further extend through a part of the thickness of the contact pad 104. The through hole 105 may be in an inverted trapezoid or a stepped shape, that is, the through hole may have an inverted trapezoid cross section or a stepped cross section.

The passivation layer 106 serves as an electrical insulation layer for the electrical connection layer 108. In an embodiment of the present disclosure, the passivation layer 106 is made of an inorganic dielectric material of oxide or nitride, such as silicon oxide, silicon nitride, silicon oxynitride or a stack thereof. As the electrical insulation layer for the electrical connection layer, the passivation layer has good step coverage even at the corners of the through hole, thus defects resulted from weakness at corners of the through hole can be avoided.

The electrical connection layer 108 covers the inner wall of the above through hole and extends onto the second surface on two sides of the through hole for connection with the solder bump 122. The electrical connection layer 108 is made of a conductive material, which may be a metal material such as Al, Au and Cu.

The passivation layer 106 serving as the electrical insulation layer may be impacted in the process of soldering the bump. In view of this, in the present disclosure, the buffer layer 107 is arranged between the electrical connection layer 108 and the passivation layer 106 under the solder bump 122. The buffer layer 107 is used to absorb the impact force to the passivation layer caused by soldering the bump. The buffer layer 107 may be made of an organic macromolecule photoresist, such as an epoxy resin or an acrylic resin. The thickness of the buffer layer 107 may range from 5 μm to 25 μm. More preferably, the buffer layer 107 may be made of a photosensitive resist. In this case, in addition to absorbing the impact force to the passivation layer, the buffer layer can also have a light absorbing function, and is capable of preventing light from entering the image sensing region through the second surface.

Further, in another embodiment of the present disclosure, a light shielding layer 101 may be provided on the second surface. As shown in FIG. 3, the light shielding layer 101 covers the image sensing region 102 for preventing light, especially infrared light, from entering the image sensing region 102 through the chip. The light shielding layer 101 may be made of a metal material, such as aluminum, aluminum alloy or another suitable metal material, so that the light undergoes specular reflection at the surface of the light shielding layer, thereby preventing the light from entering the image sensing region. More preferably, the metal material may be blackened metal Al which also has good light absorption performance.

In addition, a solder mask 120 is formed on the image sensing chip described above. The solder mask 120 covers the electrical connection layer 108 and fills the through hole. The solder mask serves as an insulation and protection layer for other layers in the process of soldering the bump. The solder mask may be made of, for example, photosensitive solder mask ink. The solder mask may be made of the same dielectric material as the buffer layer 107, for further absorbing the impact force to the passivation layer caused by soldering the bump and protecting the image sensing chip.

The solder bump 122 is electrically connected with the electrical connection layer 108. In this embodiment, the solder bump 122 is arranged on the electrical connection layer 108 on the second surface 1002 on two sides of the through hole, and is in contact and in connection with the electrical connection layer. The solder bump is used for electrical connection with the external circuit. The solder bump 122 may be a connection structure such as a solder ball or a metal pillar, and may be made of a metal material such as copper, aluminum, gold, tin or lead.

The embodiments of the package for an image sensing chip of the present disclosure are described in detail above. In addition, a packaging method for the above-described package is further provided according to the present disclosure. The packaging method is described in detail below with reference to the specific embodiments.

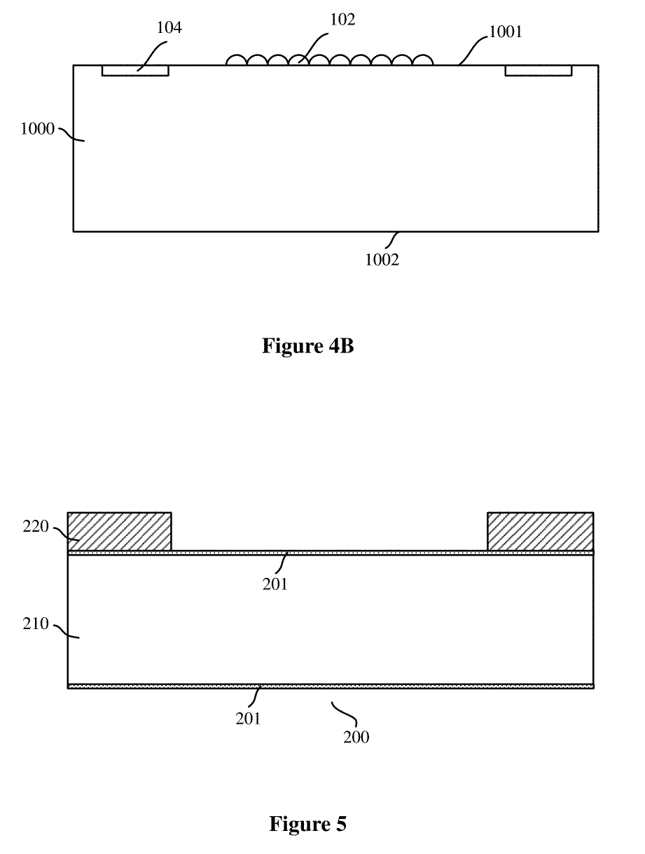

First, a wafer 1000 is provided. The wafer 1000 includes multiple image sensing chips arranged in an array. In an embodiment of the present disclosure, as shown in FIG. 4A, multiple image sensing chips 100 are formed on the wafer 1000, and are arranged in an array. Cutting trench regions 1100 are provided between adjacent image sensing chips 100 for cutting the wafer 1000 in a subsequent process to form independent image sensing chip packages. Referring to FIG. 4B, the image sensing chip 100 includes a first surface 1001 and a second surface 1002 opposite to each other. The image sensing chip 100 is provided with an image sensing region 102 and a contact pad 104 around the image sensing region. The image sensing region 102 and the contact pad 104 are located on the first surface 1001. FIG. 4A is a plan view illustrating a structure of the wafer 1000. FIG. 4B and subsequent related drawings are cross-sectional views illustrating a structure of the image sensing chip 100 along AA1.

In this embodiment, the wafer 1000 is a semiconductor substrate, which may be a bulk substrate or a stacked substrate including a semiconductor material, such as a Si substrate, a Ge substrate, a SiGe substrate, or an SOI substrate.

In an embodiment of the present disclosure, the image sensing chip includes the image sensing region 102 and the contact pad 104 around the image sensing region. The image sensing region 102 and the contact pad 104 are located on the first surface 1002. The image sensing region 102 is used for receiving external light and converting the external light into an electrical signal. At least an image sensor unit is formed in the image sensing region 102. The image sensor unit may be formed by multiple photodiodes arranged in an array, for example. An association circuit connected with the image sensor unit may be further formed in the image sensing region 102. The association circuit may be a driving unit (not shown in the drawings) for driving the chip, a reading unit (not shown in the drawings) for acquiring a photosensitive region current, a processing unit (not shown in the drawings) for processing the photosensitive region current, and the like.

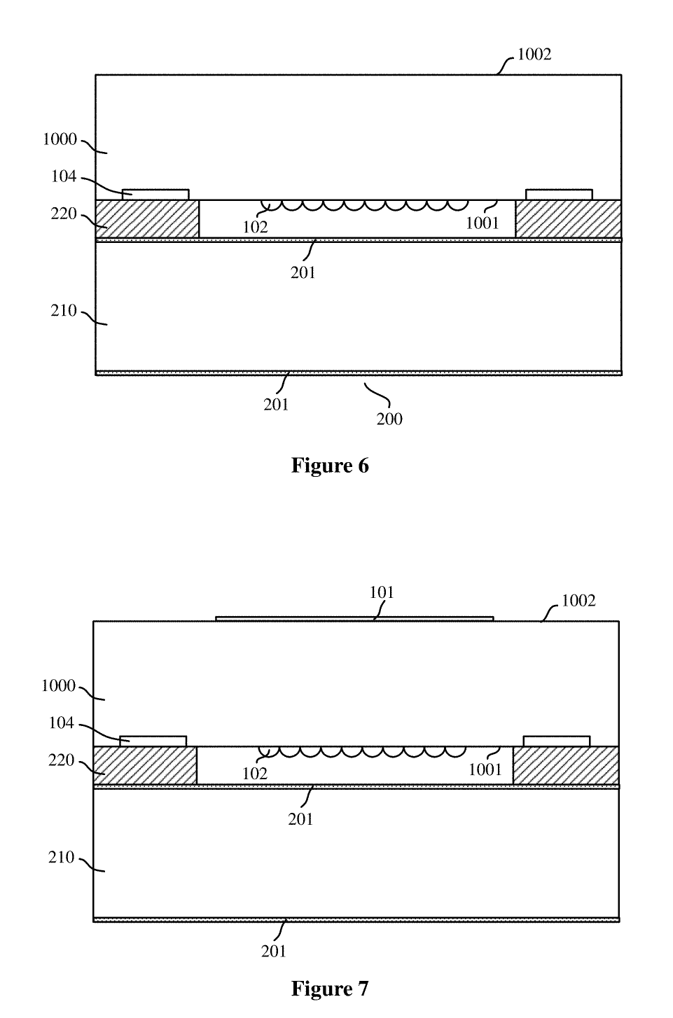

Preferably, but not necessarily, the packaging method may further include providing a protective cover plate 200, and attaching and aligning the protective cover plate 200 with the wafer 1000, as shown in FIGS. 5 to 6.

In this embodiment, as shown in FIG. 6, the protective cover plate 200 is made of optical glass on which a support structure 220 is provided. The protective cover plate 200 is attached and aligned with the image sensing region 102 via the support structure 220, so that the image sensing region 102 in contained in a cavity formed by the support structure 220, thereby forming a glass cover for protecting the image sensing region 102. The optical glass may be inorganic glass, organic glass or another transparent material with certain strength. A thickness of the optical glass may range from 300 μm to 500 μm.

The support structure 220 is generally made of a dielectric material, such as silicon oxide, silicon nitride, silicon oxynitride, or a photosensitive resist. In a specific embodiment, the support structure is made of a photosensitive resist. First, the photosensitive resist may be spin-coated on a surface of the optical glass and then exposed and developed to form the support structure 220 on the photosensitive glass.

The protective cover plate made of the optical glass may have a defect of specular reflection, which causes reduction of the light entering the image sensing region and affects the imaging quality. Therefore, referring to FIG. 5, an anti-reflection layer 201 is provided on a surface of the optical glass before the support structure is formed. The anti-reflection layer 201 may be provided on a surface of the optical glass facing the image sensing region 102 or a surface opposite to the surface facing the image sensing region 102. Alternatively, the anti-reflection layer 201 may be provided on both surfaces of the optical glass. The anti-reflection layer may be formed on the glass substrate with a spraying process. The anti-reflection layer covers at least a region corresponding to the image sensing region 102. A suitable material of the anti-reflection coating may be selected according to the selected glass substrate.

In this embodiment, as shown in FIG. 6, the protective cover plate 200 is attached with the first surface of the wafer 1000 via the support structure 220, where the protective cover plate 200 is attached and aligned with the image sensing region 102. Here, an adhesive layer (not shown in the drawings) may be provided on the support structure 220 and/or the first surface of the wafer 1000 for attaching and aligning the protective cover plate 200 with the image sensing region 102, thereby achieving attachment and alignment between the protective cover plate 200 and the wafer 1000. For example, the adhesive layer may be provided on the surface of the support structure 220 and/or at a position on the first surface of the wafer 1000 corresponding to the support structure 220 with a spraying process, a spin-coating process or an adhesion processes. Then the support structure 220 and the wafer 1000 are pressed, and are attached by the adhesive layer. The adhesive layer performs an adhesive function, as well as an insulation function and a sealing function. The adhesive layer may be made of a polymeric adhesive material, which may be a polymeric material such as silica gel, epoxy resin, or benzocyclobutene.

Next, a through hole 105 extending to the contact pad 104 is formed on the second surface 1002. The contact pad 104 is electrically connected with an external circuit through the through hole 105, to transmit the electrical signal from the image sensing region 102 to the external circuit.

Specifically, first, the wafer 1000 is thinned from the second surface 1002 to facilitate subsequent etching for forming the through hole. The wafer 1000 may be thinned with a mechanical chemical polishing process, a chemical mechanical polishing process or a combination thereof.

Next, preferably, a light shielding layer 101 may be provided at least at a position on the second surface corresponding to the image sensing region 102 in order to avoid or reduce light, especially infrared light, entering the image sensing region 102 through the second surface, as shown in FIG. 7. The light shielding layer 101 may be made of a metal material, which may be, for example, aluminum, aluminum alloy or another suitable metal material. In a preferred embodiment, first, a metal layer, such as an aluminum metal layer, may be formed on the second surface of the wafer 1000 with a sputtering process; next, the metal layer is blacked to form a black sulfide film layer on the aluminum metal layer, for improving the light shielding effect of the aluminum material layer. The metal layer may be blackened using an acid solution or an alkali solution. For example, the aluminum metal layer may be treated with an alkali solution containing sulfur. The thickness of the blackened metal layer may range from 1 μm to 10 μm. Preferably, the thickness may be 5 μm, 6 μm and the like. Then, the metal material layer is patterned to form the light shielding layer 101 only at the position on the second surface corresponding to the image sensing region 102. The light shielding layer may also have an area greater than that of the image sensing region 102 to completely cover the image sensing region, thereby achieving better light shielding effect.

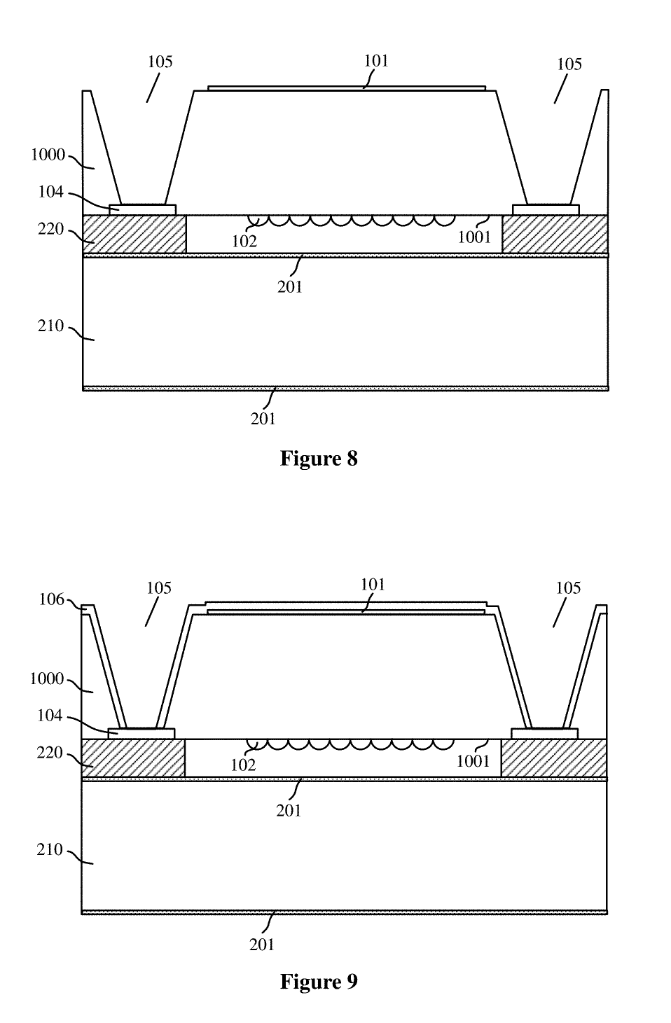

Then, a through hole 105 extending to the contact pad 104 is formed on the second surface 1002, as shown in FIG. 8. Specifically, the wafer 1000 may be etched using an etching technique, such as the reactive ion etching technique or the inductively coupled plasma etching technique, until the contact pad 104 is exposed, and the contact pad 104 may be further over etched, that is, a part of the thickness of the contact pad may be removed by etching, to form the through hole 105 through which the contact pad is exposed.

Next, the passivation layer 106 is formed on a side wall of the through hole 105 and on the second surface 1002 on two sides of the through hole 105, as shown in FIG. 9. The passivation layer 106 may be made of a dielectric material of oxide or nitride, such as silicon oxide, silicon nitride, silicon oxynitride or a stack layer thereof. Specifically, first, a passivation material layer such as a silicon oxide layer is deposited using a chemical vapor deposition method. Next, a masking process is performed, where etching is performed with the passivation material layer being masked by a mask, to remove the passivation material layer on the contact pad 104, so that the passivation layer 106 is formed on only the side wall of the through hole 105 and the second surface 1002 on two sides of the through hole 105.

The electrical insulation layer formed by the passivation layer has better coverage. Moreover, the passivation layer on the contact pad may be selectively removed using an etching process, thereby achieving a surface to surface contact between the electrical connection layer which is formed subsequently and the contact pad, thus a better contact and binding between the electrical connection layer and the contact pad can be ensured.

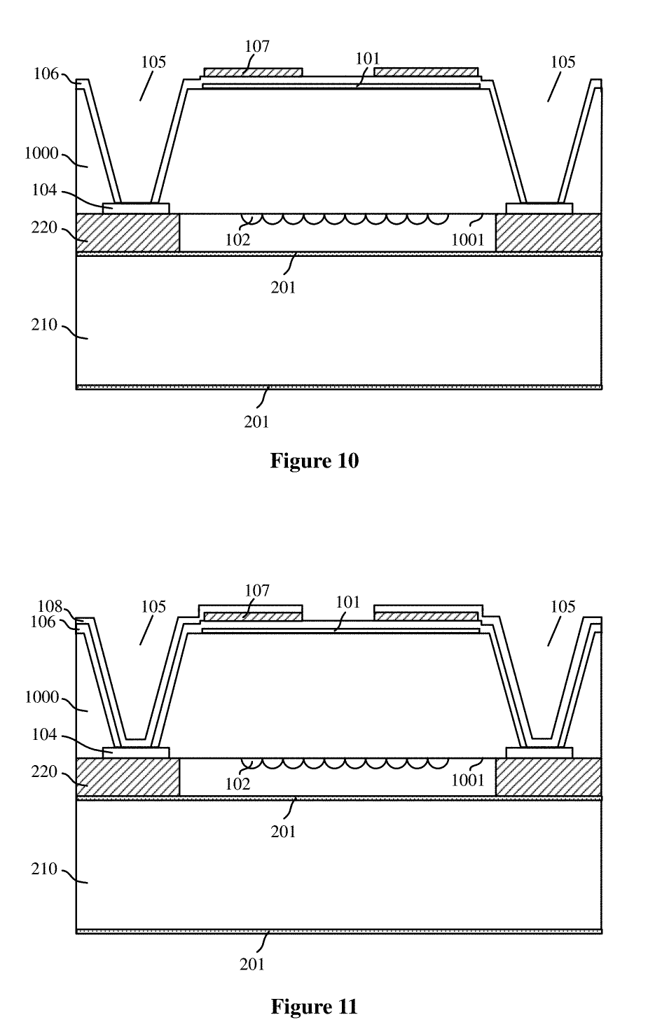

Then, preferably but not necessarily, a buffer layer 107 is formed on the passivation layer 106 on the second surface 1002, as shown in FIG. 10. The buffer layer 107 may be made of an organic macromolecule photoresist, such as an epoxy resin or an acrylic resin. More preferably, the buffer layer may be made of a photosensitive resist. A buffer material layer may be formed with a spin-coating process or a spraying process, and then the buffer material layer is exposed and developed, to form the buffer layer 107 on only the passivation layer 106 on the second surface 1002. The buffer layer is formed in at least a region on the second surface where the solder bump is arranged, or further extends along the electrical connection layer to be formed, where in the latter case, the buffer layer has an area greater than that of the region where the solder bump is arranged.

Next, an electrical connection layer 108 covering an inner wall of the through hole 105 and the buffer layer 107 is formed, as shown in FIG. 11. The electrical connection layer is made of a conductive material, which may be a thin film of a metal material, such as Al, Au, or Cu. The electrical connection layer may be formed with a RDL (Redistribution Layer) technology or other suitable deposition process. For example, electroplating of Cu is performed using the RDL technology and Ti is sputtered for forming a prim layer, to form the electrical connection layer 108. With the RDL technology, the layout of the bonding area is rearranged, thereby better meeting the requirements on the minimum pitch of the solder bumps in the bonding area.

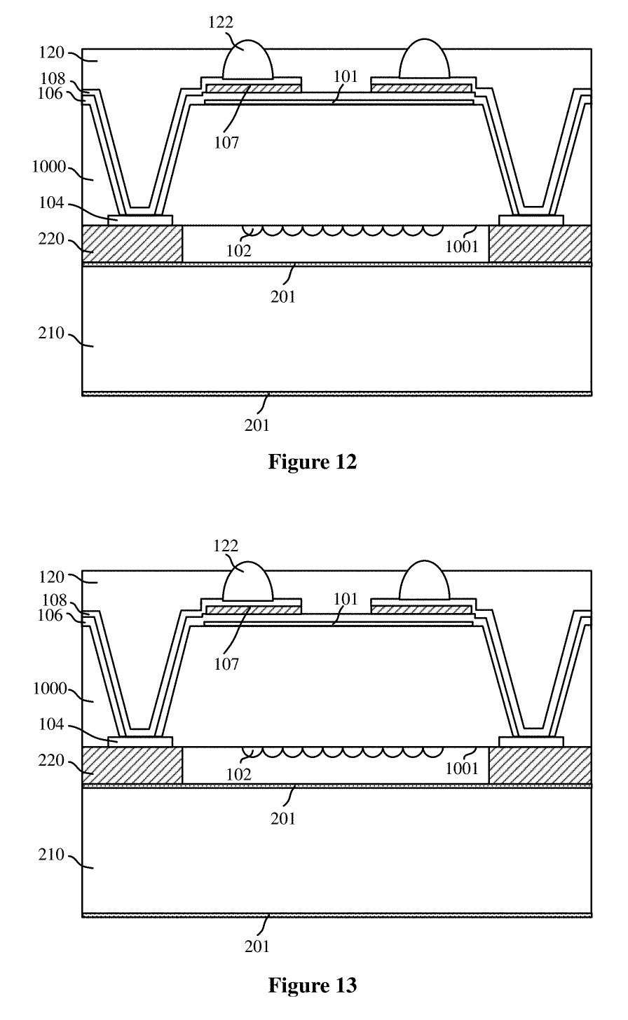

Next, a solder mask 120 is formed. Preferably, an opening is formed in the solder mask 120 on the second surface, as shown in FIG. 12. The solder mask 120 functions as an insulation and protection layer for other layers in the process of soldering the bump. The solder mask may be made of, for example, photosensitive solder mask ink, or may be made of the same material as the buffer layer 107, such as an organic macromolecule photoresist, to further absorb the impact force to the passivation layer caused by soldering the bump. The opening may be formed in the solder mask with an etching process, the electrical connection layer 108 is exposed through the opening, and the solder bump is to be formed in the opening. In a specific embodiment, the solder mask is made of photosensitive solder mask ink, and is formed by spin-coating, and the opening is formed with an exposure and development process, as shown in FIG. 12.

Next, the solder bump 122 is formed in the opening, as shown in FIG. 13. In a specific embodiment, a UBM (Under Bump Metal) layer may be formed first. Then, a bumping process is performed, where a solder ball is placed on the UBM through a reticle. Next, a reflow soldering process is performed, to form the solder bump 122 in the opening. The solder bump may be a connection structure such as a solder ball, or a metal pillar, and may be made of a metal material such as copper, aluminum, gold, tin or lead or alloy material thereof.

Further, a cutting process may be performed, where the wafer 1000 and the protective cover plate 200 are cut along the cutting trench region 1100 of the wafer 1000, to cut the wafer package described above into individual chips, thereby acquiring independent packages of image sensing chips.

In addition, in other embodiments, a difference from the packaging method according to the above embodiment is: no light shielding layer is formed on the second surface, and the buffer layer 107 is made of a photosensitive resist having a light absorption function, such that the impact force to the passivation layer can be relieved, and light can be prevented from entering the image sensing region through the second surface. In these embodiments, other manufacturing processes are the same as those in the above embodiments, and are not repeated here.

Although the present disclosure is described above, the present disclosure is not limited thereto. Those skilled in the art can make various variations and modifications without departing from the spirit and scope of the present disclosure, therefore, the protection scope of the present disclosure should confirm to the scope defined in the claims.

1. A package for an image sensing chip, comprising:
an image sensing chip having a first surface and a second surface opposite to each other, wherein the first surface is provided with an image sensing region and a contact pad around the image sensing region;
a through hole extending from the second surface to the contact pad;
a passivation layer provided on a side wall of the through hole and on the second surface;
an electrical connection layer provided on a bottom of the through hole and on the passivation layer, wherein the electrical connection layer is electrically connected with the contact pad; and
a solder bump electrically connected with the electrical connection layer.

2. The package according to claim 1, further comprising a light shielding layer located on the second surface and covering the image sensing region.

3. The package according to claim 2, wherein the light shielding layer is made of metal.

4. The package according to claim 3, wherein the metal is Al, of which a surface is blackened.

5. The package according to claim 1, further comprising a buffer layer located between the electrical connection layer and the passivation layer.

6. The package according to claim 5, wherein the buffer layer is made of an organic macromolecule photoresist or a photosensitive resist.

7. The package according to claim 6, wherein a thickness of the buffer layer ranges from 5 μm to 25 μm.

8. The package according to claim 1, further comprising a solder mask covering the electrical connection layer and filling the through hole.

9. The package according to claim 1, further comprising a protective cover plate attached and aligned with the image sensing chip.

10. The package according to claim 9, wherein the protective cover plate is made of optical glass, and an anti-reflection layer is arranged on at least one surface of the optical glass.

11. The package according to claim 1, wherein the passivation layer is made of silicon oxide, silicon nitride or silicon oxynitride.

12. A method for packaging an image sensing chip, comprising:
providing a wafer comprising a plurality of image sensing chips arranged in an array, wherein each of the plurality of image sensing chips has a first surface and a second surface opposite to each other, and comprises an image sensing region and a contact pad around the image sensing region, with the image sensing region and the contact pad being located on the first surface;
forming a through hole on the second surface, wherein the through hole extends to the contact pad;
forming a passivation layer on a side wall of the through hole and on the second surface on two sides of the through hole;
forming an electrical connection layer covering an inner wall of the through hole and a buffer layer, wherein the electrical connection layer is electrically connected with the contact pad; and
forming a solder bump on the electrical connection layer, wherein the solder bump is electrically connected with the electrical connection layer.

13. The method according to claim 12, wherein before the forming the through hole, the method further comprises forming a light shielding layer at a position on the second surface corresponding to the image sensing region.

14. The method according to claim 13, wherein the forming the light shielding layer comprises forming a metal layer on the second surface by sputtering, and etching the metal layer, to form the light shielding layer at the position corresponding to the image sensing region.

15. The method according to claim 14, wherein the metal layer is made of Al, and after forming the metal layer made of Al by sputtering, the method further comprises:
blackening a surface of the metal layer, and then etching the metal layer.

16. The method according to claim 12, wherein after the forming the electrical connection layer and before the forming the solder bump, the method further comprises:
forming a solder mask, and
forming an opening in the solder mask on the second surface, wherein the solder bump is formed in the opening.

17. The method according to claim 12, further comprising:
providing a protective cover plate, and attaching and aligning the protective cover plate with the image sensing chip.

18. The method according to claim 17, wherein the protective cover plate is made of optical glass, and an anti-reflection layer is arranged on at least one surface of the optical glass.

19. The method according to claim 12, wherein the forming the passivation layer on the side wall of the through hole and on the second surface on two sides of the through hole comprises:
depositing a passivation layer; and
removing the passivation layer at a bottom of the through hole by etching.

20. The method according to claim 19, wherein the passivation layer is made of silicon oxide, silicon nitride or silicon oxynitride.

21. The method according to claim 12, wherein after the forming the passivation layer, the method further comprises:
forming the buffer layer on the passivation layer on the second surface.

22. The method according to claim 21, wherein the buffer layer is made of a photosensitive resist, and the forming the buffer layer on the passivation layer on the second surface comprises:
spin-coating the photosensitive resist on the second surface; and
forming the buffer layer with an exposure and development process.
